(19) United States
(12) Patent Application Publication
(10) Pub. No.: US 2026/0215024 A1
(43) Pub. Date: Jul. 23, 2026

(54) Electrode structure, back-contact solar cell, cell assembly, and photovoltaic system

(71) Applicant: ZHEJIANG AIKO SOLAR ENERGY TECHNOLOGY CO., LTD., Yiwu City, JinHua, Zhejiang (CN)

(72) Inventors: Gang CHEN, Yiwu City, Zhejiang (CN); Yongqian WANG, Yiwu City, Zhejiang (CN); Xinqiang YANG, Yiwu City, Zhejiang (CN)

(73) Assignee: ZHEJIANG AIKO SOLAR ENERGY TECHNOLOGY CO., LTD., Yiwu City, JinHua, Zhejiang (CN)

(21) Appl. No.: 19/137,131

(22) PCT Filed: Oct. 17, 2023
(86) PCT No.: PCT/EP2023/078728

§ 371 Date: Jun. 9, 2025

(30) Foreign Application Priority Data
Dec. 12, 2022 (CN) 202211588511.0

(51) Int. Cl. H10F 77/20; H10F 10/10; H10F 19/90; H10F 77/00

(52) U.S. Cl. CPC H10F 77/219; H10F 10/10; H10F 19/908; H10F 77/215; H10F 77/937

(57) ABSTRACT

An electrode structure, a back-contact solar cell, a cell assembly, and a photovoltaic system are provided. A plurality of first fingers of the electrode structure include at least one first collection grid line and at least one first confluence grid line; the first busbar includes a first edge busbar disposed on one side near the first edge of the back-contact solar cell, and one end of the first confluence grid line is connected to the first edge busbar, the other end passing through the first discontinuous zone on the second busbar adjacent to the first edge busbar is connected to the first busbar adjacent to the first edge busbar.

### PRIORITY INFORMATION

The present application claims the priority and interest of the patent application No. 202211588511.0 submitted to the China National Intellectual Property Administration on Dec. 12, 2022, and its full text is incorporated herein by reference.

### TECHNICAL FIELD

The present application relates to the field of solar cell technology, in particular to an electrode structure, a back-contact solar cell, a cell assembly, and a photovoltaic system.

### BACKGROUND ART

Back-contact solar cell is a type of cell with both the emitter and base contact electrodes disposed on its back (non light-receiving surface). The cell's light-receiving face which is not obstructed by any metal electrodes effectively increases its short-circuit current. As shown in FIG. 1, in related technologies, in order to converge the fingers of same polarity, generally insulating adhesive 3 is printed on those of opposite polarity to form insulation, with others of same polarity exposed, and solder joint 1 and busbar 2 are then printed to make the fingers of same polarity in contact to converge those of different polarity. In such a case, however, insulating adhesive 3 may not withstand high temperatures, while solder joint 1 and busbar 2 are formed by post-printing, and only low-temperature paste may be selected for them, which means increased costs and reliability issues. Moreover, insulating adhesive 3 is about 30 um high for a good insulation, solder joint 1 and busbar 2 are required to be higher than 30 um to avoid wire breakage, which will result in an increasing paste consumption and higher costs. In addition, poor adhesion may occur between insulating adhesive 3 and some of the paste.

The electrode pattern of the back-contact solar cell may be designed as shown in FIGS. 2 and 3 to solve the problem in FIG. 1. In FIG. 2, the finger 4 is disconnected at the opposite solder joint 5 and busbar 6 which are located at the extreme edge of the silicon wafer. During the assembly manufacturing, as a result, the solder strip also needs to cover the edge of silicon wafer. A large number of micro cracks at the edge of silicon wafer will easily cause stress concentration during the welding process of solder strip, leading to cracking, reduced component yield and reliability.

In FIG. 3, the finger 7 is disconnected at the opposite solder joint 8 and busbar 9. The solder joint 8 and busbar 9 on the outside are at a certain distance from the extreme edge of silicon wafer, and are provided with the same polarity on the periphery. Although the design in FIG. 3 solves the problems in FIG. 2, the photogenerated electron holes need to diffuse to the opposite region before an effective collection is realized. For FIG. 3, the photogenerated electron holes in the outer edge region need to span a distance of mm or even cm level before reaching the opposite region. The composite loss during the long-distance diffusion will cause a decrease in short-circuit current and increase string resistance, resulting in a loss of fill factor and very poor photoelectric conversion performance.

Designing an electrode structure for back-contact solar cells to solve the above problems has therefore always been one of the key research issues for person skilled in the art.

### SUMMARY OF THE INVENTION

The present application provides an electrode structure, a back-contact solar cell, a cell assembly, and a photovoltaic system.

The present application is implemented in such a way that an electrode structure of the embodiment is used for a back-contact solar cell that includes a first polar region and a second polar region which are alternatively arranged, and the electrode structure includes:
a plurality of first fingers and a plurality of second fingers, which are alternately spaced, and the plurality of first fingers are used to collect current in the first polar region, and the plurality of second fingers are used to collect current in the second polar region; and
a plurality of first busbars and a plurality of second busbars, which are alternately spaced, and an arrangement direction of the first busbar and the second busbar is different from that of the first finger and the second finger; the plurality of first busbars are connected to the plurality of first fingers, and the plurality of second busbars are connected to the plurality of second fingers;
the plurality of first fingers include at least one first collection grid line and at least one first confluence grid line, and the at least one first collection grid line is disconnected at the second busbars, and the plurality of first busbars include a first edge busbar located on a side near a first edge of the back-contact solar cell, and at least one first discontinuous zone is formed at the second busbar adjacent to the first edge busbar; one end of the at least one first confluence grid line is connected to the first edge busbar, and the other end of the at least one first confluence grid line passing through the at least one first discontinuous zone is connected to the first busbar adjacent to the first edge busbar;
no solder joints are provided on the first edge busbar and/or the first edge busbar is not used for welding;
the first edge busbar is located at the first edge.

The present application also provides a back-contact solar cell including the electrode structure as described in any of the above items, the electrode structure is disposed on the back surface of the back-contact solar cell.

The present application also provides a cell assembly, including the back-contact solar cell mentioned above.

The present application also provides a photovoltaic system, including the aforementioned cell assembly.

A part of the additional aspects and advantages of the present application will be provided in the following, and some will become apparent or may be learned through the practice of the application.

### BRIEF DESCRIPTION OF THE DRAWINGS

FIG. 1 is a schematic diagram of the graphic design of the first electrode in the prior art;

FIG. 2 is a schematic diagram of the graphic design of the second electrode in the prior art;

FIG. 3 is a schematic diagram of the graphic design of the third electrode in the prior art;

FIG. 4 is a schematic diagram of the module of photovoltaic system provided in the embodiment of the present application;

FIG. 5 is a schematic diagram of the module of the cell assembly provided in the embodiment of the present application;

FIG. 6 is a structural schematic diagram of the electrode structure provided in the embodiment of the present application;

FIG. 7 is another structural schematic diagram of the electrode structure provided in the embodiment of the present application;

FIG. 8 is yet another structural schematic diagram of the electrode structure provided in the embodiment of the present application;

FIG. 9 is still another structural schematic diagram of the electrode structure provided in the embodiment of the present application;

FIG. 10 is still another structural schematic diagram of the electrode structure provided in the embodiment of the present application;

FIG. 11 is still another structural schematic diagram of the electrode structure provided in the embodiment of the present application;

FIG. 12 is still another structural schematic diagram of the electrode structure provided in the embodiment of the present application;

FIG. 13 is still another structural schematic diagram of the electrode structure provided in the embodiment of the present application;

FIG. 14 is still another structural schematic diagram of the electrode structure provided in the embodiment of the present application.

### DETAILED DESCRIPTION OF EMBODIMENTS

In order to make the object, technical schemes and advantages of the present application clearer, the present application will be further described in detail with reference to the accompanying drawings and embodiments. The examples of the embodiments are shown in the accompanying drawings, where the same or similar labels throughout represent the same or similar elements or the elements with the same or similar functions. The embodiments described below with reference to the accompanying drawings are exemplary and are only intended to explain the present application and may not be understood to limit the present application. In addition, it should be understood that the specific embodiments described here are intended for illustrating rather than limiting the present application.

In the description of the present application, it should be understood that, the terms “up”, “down”, “left”, “right”, “horizontal”, and “vertical” indicate the orientation or position relationship based on the orientation or position relationship shown in the attached drawings, only for the convenience of simple description of the present application, rather than indicating or implying that the devices or elements referred to must have a specific orientation, be constructed and operated in a specific orientation, and therefore may not be understood as a limitation on the present application.

In addition, the terms like “first” and “second” are only for illustrative purposes and may not be understood as indicating or implying relative importance or the number of technical features referred to. Therefore, the features defined with “first” and “second” may explicitly or implicitly include at least one or a plurality of features. In the description of the present application, the meanings of “a plurality of”, “pieces of”, and “a number of” refer to two or more, unless otherwise specified.

In the present application, unless otherwise specified and limited, the first feature “above” or “below” the second feature may include direct contact between the first and second features, or direct contact between the first and second features through additional features between them. Moreover, the first feature “over”, “above” and “on” the second feature includes the first feature being directly above and diagonally above the second feature, or simply indicating that the first feature is horizontally higher than the second feature. The first feature “below”, “beneath”, and “under” the second feature includes the first feature directly below and diagonally below the second feature, or simply indicating that the horizontal height of the first feature is less than that of the second feature.

The following disclosure provides many different embodiments, or examples, to implement different features in the present application. The components and arrangements of specific examples are described below to simplify the disclosure of the present application. These are, of course, merely examples that are not intended to limit the present application. In addition, the present application may repeat reference numerals and/or letters in the various examples. This repetition is for the purpose of simplicity and clarity and does not in itself dictate a relationship between the various embodiments and/or configurations discussed. In further, the application provides examples of various specific processes and materials, but person of ordinary skill in the art may be aware of the application of other processes and/or the usage scenarios of other materials.

In the electrode structure, back-contact solar cell, cell assembly, and photovoltaic system of the present embodiment, the first collection grid line of the first finger is disconnected at the second busbar, and the first edge busbar of the first busbar is connected to the first collection grid line in the first finger to collect the current in the first polar region near the first edge through the first collection grid line, and the first confluence grid line passes through the first discontinuous zone on the second busbar adjacent to the first edge busbar to connect the first edge busbar as well as the first busbar adjacent to the first edge busbar. The current collected by the first edge busbar may be transmitted for convergence and collection purpose through the first confluence grid line to the first busbar adjacent to the first edge busbar. In this way, the current in the edge area collected by the first edge busbar which is disposed on the side near the first edge of the back-contact solar cell, may directly converge through the first confluence grid line, and the first busbar adjacent to the first edge busbar, dispense with any welding on the first edge busbar, which may avoid stress concentration during welding and improve the yield and reliability of assembly. Meanwhile, the photogenerated electron holes near the first edge may, without spanning a long distance, reach the opposite region to collect the current and fully ensures a high photoelectric conversion.

In the present application, the current in the edge area collected by the first edge busbar which is disposed on the side near the first edge of the back-contact solar cell, may directly converge through the first confluence grid line, and the first busbar adjacent to the first edge busbar, dispense with any welding on the first edge busbar, which may avoid stress concentration during welding and improve the yield and reliability of assembly. Meanwhile, the photogenerated electron holes near the first edge may, without spanning a long distance, reach the opposite region to collect the current and fully ensures a high photoelectric conversion.

### Embodiment 1

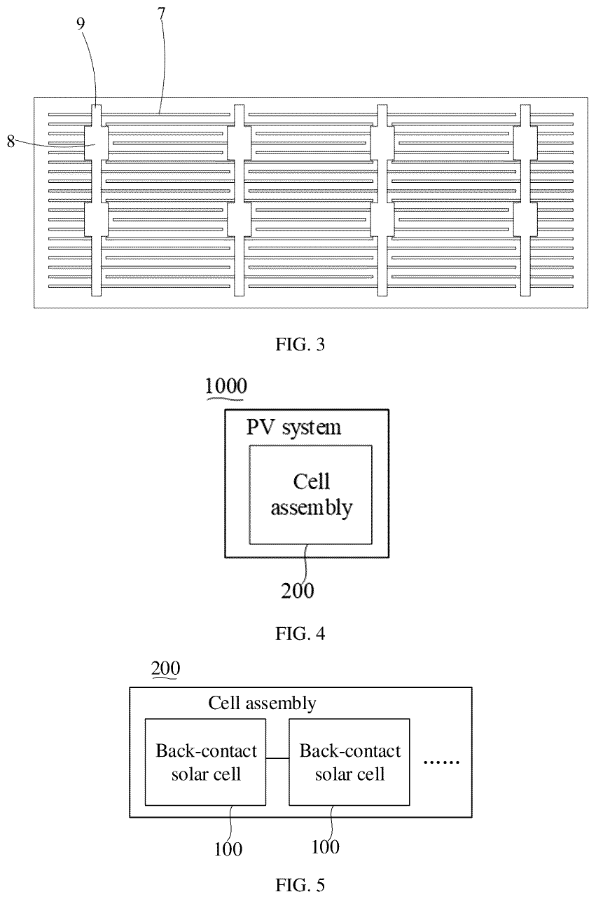

Referring to FIGS. 4 to 5, the photovoltaic system 1000 in the embodiment of the present application may include the cell assembly 200, which in further include a plurality of back-contact solar cells 100 in the embodiment of the present application.

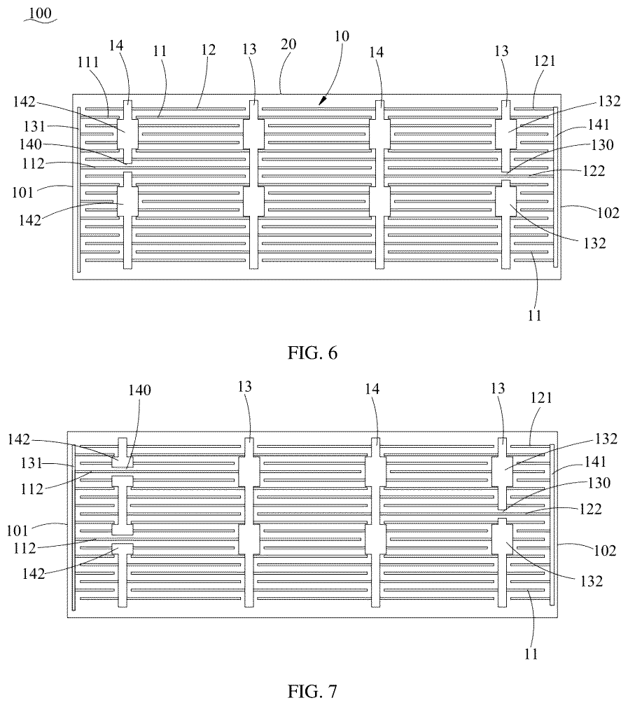

Referring to FIG. 6, the back-contact solar cell 100 in the embodiment of the present application may include a substrate 20 and an electrode structure 10 in the embodiment of the present application. The substrate 20 may be a silicon wafer, and the back of the substrate 20 is alternatively provided with the first polar region and the second polar region having mutually opposite polarities. The first polar region and the second polar region, for example, may be a P-type doped region and an N-type doped region, respectively; for another instance, the first polar region and the second polar region may be an N-type doped region and a P-type doped region, respectively, which are not limited here.

Referring to FIG. 6, the electrode structure 10 in the embodiment of the present application may be disposed on the back surface of the back-contact solar cell 100, and the electrode structure 10 may include a plurality of first fingers 11 and a plurality of second fingers 12, which are alternately spaced, as well as a plurality of first busbars 13 and a plurality of the second busbars 14, which are alternately spaced.

The first finger 11 is used to collect the current in the first polar region, and the second finger 12 is used to collect the current in the second polar region, that is, the first finger 11 can correspond to the first polar region, and the second finger 12 may correspond to the second polar region, respectively.

The first busbar 13 and the second busbar 14 are arranged in a direction different from that of the first finger 11 and the second finger 12. The first busbar 13 is connected to the first finger 11, and the second busbar 14 is connected to the second finger 12, that is, the first busbar 13 may be used to pool the current collected by the first finger 11, and the second busbar 14 may be used to pool the current collected by the second finger 12.

As shown in FIG. 6, the plurality of first fingers 11 include first collection grid lines 111 and at least one first confluence grid line 112; the first collection grid line 111 is disconnected at the second busbar 14, and the plurality of first busbars 13 include a first edge busbar 131 (i.e. the leftmost first busbar 13 in FIG. 6) which, located on a side near a first edge 101 of the back-contact solar cell 100, at least one first discontinuous zone 140 is formed at the second busbar 14 adjacent to the first edge busbar 131 (i.e. the first second busbar 14 from left to right in FIG. 6). One end of the at least one first confluence grid line 112 is connected to the first edge busbar 131, and the other end passing through the at least one first discontinuous zone 140 is connected to the first busbar 13 adjacent to the first edge busbar 131 (i.e. the second first busbar 13 from left to right in FIG. 6), and the position where the first confluence grid line 112 passes through the first discontinuous zone 140 is insulated and isolated from the second busbar 14.

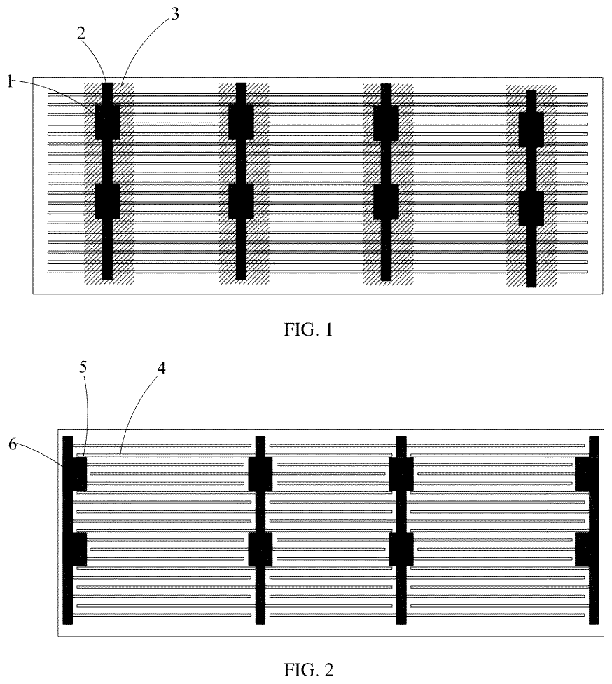

In the electrode structure 10, back-contact solar cell 100, cell assembly 200, and photovoltaic system 1000 of the present embodiment, the first collection grid line 111 of the first finger 11 is disconnected at the second busbar 14, and the first edge busbar 131 of the first busbar 13 is connected to the first collection grid line 111 in the first finger 11 to collect the current in the first polar region near the first edge 101 through the first collection grid line 111, and the first confluence grid line 112 passes through the first discontinuous zone 140 on the second busbar 14 adjacent to the first edge busbar 131 to connect the first edge busbar 131 as well as the first busbar 13 adjacent to the first edge busbar 131. The current collected by the first edge busbar 131 may be transmitted for convergence and collection purpose through the first confluence grid line 112 to the first busbar 13 adjacent to the first edge busbar 131. In this way, compared to the electrode pattern design in FIG. 2 of the prior art, the current in the edge area collected by the first edge busbar 131 in the present application which is disposed on the side near the first edge 101 of the back-contact solar cell 100, may directly converge through the first confluence grid line 112, and the first busbar 13 adjacent to the first edge busbar 131, dispense with any welding on the first edge busbar 131, which may avoid stress concentration during welding and improve the yield and reliability of assembly. Compared to the graphic design of electrode in FIG. 3 of the prior art, meanwhile, the photogenerated electron holes near the first edge 101 may, without spanning a long distance, reach the opposite region to collect the current and fully ensures a high photoelectric conversion.

Specifically, in the embodiment of the present application, the first polar region and second polar region have opposite polarities, so do the first finger 11 and the second finger 12. For example, the first finger 11, a positive finger line, is used to collect positive current in the positive electrode area, while the second finger 12, a negative finger line, is used to collect negative current in the negative electrode area; alternatively, the first finger 11, a negative finger electrode, is used to collect negative current in the negative electrode area, and the second finger 12, a positive grid line electrode, is used to collect positive current in the positive electrode area. The positive finger line is disposed in the P-type doped region of the back-contact solar cell 100, and the negative finger line is disposed in the N-type doped region of the back-contact solar cell 100.

As shown in FIG. 6, in the embodiment shown in FIG. 6, the first busbars 11 and the second busbars 12 are alternatively arranged in the vertical direction, and are both horizontal to the upper and lower edge lines of the back-contact solar cell 100, correspondingly, the first polar region and the second polar region are also alternately arranged in a vertical direction.

The first busbar 13 and the second busbar 14 may be, in a horizontal direction, vertically arranged alternately with the first finger 11 and the second finger 12. Referring to FIG. 6, for example, the first finger 11 and the second finger 12 are alternately arranged in the vertical direction, and are both horizontal to the upper and lower edge lines of the back-contact solar cell 100, while the first busbar 13 and the second busbar 14 are alternately arranged in the horizontal direction, and are both horizontal to the left and right edge lines of the back-contact solar cell 100.

In the embodiment of the present application, the back-contact solar cell 100 may be substantially rectangular, and the term “substantially rectangular” means that the back-contact solar cell 100 may be a square, rectangular, or rectangular shape with standard, cut, or rounded corners, which are set according to actual production needs and are not limited here. In addition, the number of the first finger 11 and the second finger 12 is determined based on the actual area of the back-contact solar cell 100, the width of them and the distance between them, which are not limited here.

In the embodiment of the present application, “at least one first discontinuous zone 140 is formed at the second busbar 14 adjacent to the first edge busbar 131” means that the second busbar 14 adjacent to the first edge busbar 131, a discontinuous structure, is separated at the first discontinuous zone 140, that is, the second busbar 14 adjacent to the first edge busbar 131 is separated into at least two parts by the first discontinuous zone 140.

In the embodiment shown in FIG. 6, “first edge 101” refers to the left edge in FIG. 6, and “the first edge busbar 131 is located on the side near the first edge 101” means that the first edge busbar 131 is the leftmost first busbar 13 in FIG. 6, that is, the first first busbar 13 near the first edge 101 may be a certain distance from the first edge 101 of the back-contact solar cell 100, or may also be directly disposed on the first edge 101 of the back-contact solar cell 100 (i.e. the left edge in FIG. 6), which are subject to no restrictions here.

In further, as shown in FIG. 6, it may be understood that in the embodiment of the present application, the first finger 11 and the second finger 12 are alternatively disposed between the first edge busbar 131 and the second busbar 14 adjacent to the first edge busbar 131. The first collection grid line 111 in the first finger 11 between the two is connected to the first edge busbar 131, and the second finger 12 is connected to the second busbar 14 adjacent to the first edge busbar 131, and the first confluence grid line 112 passing through the first discontinuous zone 140 is connected to the first busbar 13 adjacent to the first edge busbar 131.

The first edge busbar 131 may converge the current collected by the first collection grid line 111 between the first edge busbar 131 and the second busbar 14 adjacent to the first edge busbar 131, and the current then flows through the first collection grid line 112 to the first busbar 13 adjacent to the first edge busbar 131, so that the current generated in the first polar region of the edge region near the first edge 101 is collected and converged, without welding on the first edge busbar 131, which avoids the occurrence of cracks on the edge of the back-contact solar cell 100 during the welding.

In further, in the embodiment of the present application, the first finger 11 and the second finger 12 may be aluminum grid lines, silver grid lines, copper grid lines, or silver plated copper grid lines, which are subject to no restrictions here.

It may be understood that in the embodiment of the present application, the first finger 11 and the second finger 12 may be grid lines of the same or different metals, for example, aluminum grid lines are selected for both the first finger 11 and the second finger 12; alternatively, aluminum grid line is selected for the first finger 11 and silver grid line is selected for the second finger 12.

If the first finger 11 or the second finger 12 is aluminum or silver grid lines, aluminum or silver grid lines may be printed onto the doped area of the back-contact solar cell 100 through screen printing; if the first finger 11 or the second finger 12 is copper grid lines, copper grid lines may be plated on the doped area of the back-contact solar cell 100 through electroplating or evaporation.

In the embodiment of the present application, of course, copper, silver, aluminum, or silver coated copper grid lines may also be used for the first busbar 13 and the second busbar 14, which are not subject to restrictions here. It may be understood that in the process of forming the second busbar 14 adjacent to the first edge busbar 131, a screen plate may be used to cover the position corresponding to the first discontinuous zone 140, and the second busbar 14 adjacent to the first edge busbar 131 with a first discontinuous zone 140 may be formed through printing or electroplating and evaporation.

In addition, in a preferred embodiment, since the first confluence grid line 112 is connected to the first edge busbar 131 and the first busbar 13 adjacent to the first edge busbar 131 to converge the first edge busbar 131 and the adjacent first busbar 13, the first confluence grid lines 112 may preferably be copper grid lines with smaller current loss in order to reduce the losses during the convergence, and the remaining grid lines are not limited here.

In the embodiment of the present application, a plurality of back-contact solar cells 100 in the cell assembly 200 may be sequentially connected in series to form a cell string. Each cell string may be connected in series, in parallel, or in combination, to achieve convergent current output. For example, welding strips may be used to connect cells, and a busbar may be used to connect cell strings. In the present application, for example, except for the first edge busbar 131 and the undermentioned second edge busbar 141, all other busbars may be welded with welding strips to connect various cells.

It may be understood that in the embodiment of the present application, the back-contact cell assembly 200 may also include a metal frame, a backplate, photovoltaic glass, and an adhesive film (not shown in the figure). The adhesive film may serve as a filler between the front of the back-contact solar cell 100 and the photovoltaic glass, the back and the backplate, as well as adjacent cells. The adhesive film may be a transparent colloid with good transparency and aging resistance. The adhesive film, for example, may be EVA or POE film, and may be selected according to the actual situation, which are not subject to restrictions here.

Photovoltaic glass that covers the adhesive film on the front of the back-contact solar cell 100 may be the ultra white glass having high transmittance and transparency, and excellent physical, mechanical and optical properties. Ultra white glass, for example, has a transmittance of over 92% and may, as far as possible, protect the back-contact solar cell 100 without affecting its efficiency. Meanwhile, the adhesive film may bond the photovoltaic glass and the back-contact solar cell 100 together, and the use of adhesive film may seal and insulate the back-contact solar cell 100 against water and moisture.

The backplate, which is attached to the adhesive film on the back of the back-contact solar cell 100, may protect and support the back-contact solar cell 100, and have reliable insulation, and water and aging resistance. There are a variety of options for the backplate, usually tempered glass, organic glass, aluminum alloy TPT composite adhesive film, etc., may be selected specifically according to the specific situation, which are not subject to restrictions here. The overall structure composed of the backplate, the back-contact solar cell 100, the adhesive film, and the photovoltaic glass may be disposed on the metal frame, and the metal frame serves as the main external support structure for the entire back-contact cell assembly 200 and provides stable support and installation for the back-contact cell assembly 200. The back-contact cell assembly 200, for example, may be installed in the desired position through the metal frame.

In further, in this embodiment, the photovoltaic system 1000 may be applied to photovoltaic power plants, such as ground power plants, rooftop power plants, surface power plants, etc., as well as to the equipment or devices that utilize solar energy for power generation, like users' solar power sources, solar street lights, solar cars, solar buildings, etc. It may be understood that, of course, the application scenarios of photovoltaic system 1000 are not limited to these, that is, photovoltaic system 1000 may be further applied in all fields that realize power generation based on solar energy. Taking the photovoltaic power generation system network as an example, photovoltaic system 1000 may include photovoltaic system, combiner box and inverter. The photovoltaic system may be an array combination of a plurality of back-contact cell assembly 200. A plurality of photovoltaic systems, for example, may be formed by a plurality of back-contact cell assemblies 200. The photovoltaic system is connected to combiner box which may converge the current generated by photovoltaic system, and the converged current, after flowing through the inverter and being converted into alternating current (AC) power required by the municipal power grid, is then connected to the municipal power grid to provide solar power.

In some embodiments, the first edge busbar 131 may be disposed at the first edge 101 of the back-contact solar cell 100. Specifically, “the first edge busbar 131 is located at the first edge 101” may be understood as being disposed on the edge line of the first edge 101 of the back-contact solar cell 100, or without additional fingers between the first edge busbar 131 and the edge line of the back-contact solar cell 100.

### Embodiment 2

Referring to FIG. 6, in some embodiments, no solder joints are provided on the first edge busbar 131 for welding, which may save solder joint related materials and reduce costs while also avoiding edge cracks during the welding process.

In some embodiments, the first edge busbar 131 is not used for welding so that cracks caused by welding at the edges are avoided.

In such a case, it may be understood that the first edge busbar 131 is not provided with solder joints and not used for welding, or solder joints are provided on the first edge busbar 131 but not used for welding, preferably no solder joints are provided on the first edge busbar 131 and used for welding.

### Embodiment 3

In some embodiments, a plurality of first confluence grid lines 112 and a plurality of first discontinuous zones 140 may be provided, and each first discontinuous zone 140 corresponds to at least one first confluence grid line 112.

The first edge busbar 131 and the first busbar 13 adjacent to the first edge busbar 131 may be connected through the plurality of first confluence grid lines 112 to improve the confluence efficiency.

Specifically, in such embodiments, preferably a first discontinuous zone 140 corresponds to a first confluence grid line 112, in order to avoid poor welding (such as false soldering) when the subsequent welding with the second busbar 14 adjacent to the first edge busbar 131 due to the excessive width of the first discontinuous zone 140, and to ensure the reliability of welding.

It should be noted that FIG. 6 only presents a first confluence grid line 112, and some of the fingers and busbars of the electrode structure, which merely serve as examples. It may be understood that in some embodiments, a plurality of first fingers 11 and second fingers 12, as well as first confluence grid lines 112 may also be provided below the first confluence grid line 112 in FIG. 6. The specific number may be determined based on the size of the back-contact solar cell 100, which are subject to no restrictions here.

### Embodiment 4

In some embodiments, a plurality of first confluence grid lines 112 are symmetrically arranged along the centerline of the back-contact solar cell 100 in the arrangement direction of the first finger 11 and the second finger 12.

The plurality of first confluence grid lines 112 which are symmetrically disposed may ensure that each first confluence grid line 112 has basically the same convergence path when collecting current on the first edge busbar 131, avoiding the current convergence with a larger overall losses due to the significant differences in the convergence paths that may result in varied losses on different paths.

Specifically, in such an embodiment, the plurality of first confluence grid lines 112 are symmetrically disposed along the centerline of the back-contact solar cell 100 in the arrangement direction of the first finger 11 and the second finger 12, that is, the first confluence grid lines 112 are symmetrically disposed in the two vertically symmetric areas of the back-contact solar cell 100, and the distance between any two adjacent connection points between the first edge busbar 131 and each first confluence grid line 112 is the same. During confluence, the confluence from the first edge busbar 131 to each first confluence grid line 112 basically has the same confluence path and loss, ensuring the confluence performance and improving the confluence efficiency.

It may be understood that, of course, in some embodiments, a single first confluence grid line 112 may also be disposed at the center of the back-contact solar cell 100, that is, the connection point between the single first confluence grid line 112 and the first edge busbar 131 is located at the midpoint of the first edge busbar 131.

In this way, the use of the single first confluence grid line 112 at the center position ensures that the current collected by the first confluence grid line 111 has basically the same convergence path, avoiding significant differences in convergence paths that may lead to increased overall losses and ensuring the convergence effect.

Specifically, in such an embodiment, a single first confluence grid line 112 may be connected at the midpoint of the first edge busbar 131 to divide the back-contact solar cell 100 into two vertically symmetrical regions, so that the current collected by the first collection grid line 111 in the upper and lower regions has basically the same confluence path on the first edge busbar 131, ensuring the confluence effect.

### Embodiment 5

In some embodiments, the width of the first confluence grid lines 112 may be 80 um-1.5 mm.

In this way, the first confluence grid lines 112 having a rational width within the range of 80 um-1.5 mm may ensure its convergence effect, and prevent the first confluence grid lines 112 from overheating or even melting since the first confluence grid lines 112 with too small width fail to withstand the current from the first edge busbars 131, and also avoid the waste of paste as a result of the first confluence grid lines 112 with too large width.

Specifically, in such embodiments, the width of the first confluence grid line 112 may be any one of the values from 80 um, 100 um, 200 um, 300 um, 400 um, 500 um, 600 um, 700 um, 800 um, 900 um, 1 mm, 1.1 mm, 1.2 mm, 1.3 mm, 1.4 mm, 1.5 mm, or 80 um-1.5 mm, which are subject to no restrictions here.

In further, in some embodiments, the width of the first confluence grid line 112 may be preferably greater than 1.5 times that of the first collection grid line 111.

The first confluence grid line 112 with a width greater than 1.5 times that of the first collection grid line 111 may ensure a better confluence effect and reliability.

Specifically, it may be understood that in the embodiment of the present application, the current that flows through the first confluence grid line 112 is the converged one flowing through the first edge busbar 131. The width of the first confluence grid line 112 therefore may be preferably 1.5 times larger than that of the first collection grid line 111, ensuring the first confluence grid line 112 with a larger width and better convergence reliability.

In some embodiments, the distance between the two second fingers 12 adjacent to the first confluence grid line 112 is greater than the distance between the other adjacent second fingers 12.

In this way, a larger spacing between the two second fingers 12 adjacent to the first confluence grid line 112 provides the first confluence grid line 112 with a larger width, ensuring the convergence effect and reliability.

### Embodiment 6

Referring to FIG. 6, in some embodiments, a plurality of first solder joints 142 are spaced on the second busbar 14 adjacent to the first edge busbar 131;

The first discontinuous zone 140 is located between two adjacent first solder joints 142.

The arrangement of the first discontinuous zone 140 at two adjacent first solder joints 142 may, while realizing the convergence, ensure the integrity of the first solder joint 142 and support the welding with the second busbar 14 adjacent to the first edge busbar 131.

Specifically, in such an embodiment, the plurality of first solder joints 142 may be evenly spaced on the second busbar 14 adjacent to the first edge busbar 131 (FIG. 6 only exemplify two first solder joints 142). Preferably, a single first discontinuous zone 140 is provided between the adjacent first solder joints 142 and a single first confluence grid line 112 corresponding to the first discontinuous zone 140 is provided, so that at least one first confluence grid line 112 is provided between each two first solder joints 142 to reduce the number and width of the first discontinuous zone 140 between adjacent first solder joints 142, and avoid affecting the welding with the second busbar 14 adjacent to the first edge busbar 131.

In such an embodiment, the distance between two adjacent first solder joints 142 on the second busbar 14 adjacent to the first edge busbar 131 may be greater than 5 mm, preferably greater than 9 mm. In some embodiments, in order to reduce the use of paste at the first solder joint 142 of the same size, the distance between two adjacent first solder joints 142 may be greater than 11 mm but less than or equal to 45 mm.

In further, in such embodiments, the distance between two adjacent first solder joints 142 may be preferably greater than 11 mm but less than or equal to 30 mm. The first solder joints 142 having a spacing within this optimal range may ensure the number of first solder joints 142 to provide welding reliability without poor welding, and also avoid an increasing costs due to the excessive number of first solder joints 142.

Of course, referring to FIG. 7, in some embodiments, the first discontinuous zone 140 may also be formed on the first solder joint 142, that is, a first discontinuous zone 140 is provided on the first solder joint 142.

A first discontinuous zone 140 is formed on each first solder joint 142, and both the first discontinuous zones 140 and the first confluence grid lines 112 are uniformly arranged to ensure the convergence effect.

Specifically, as shown in FIG. 7, in such a case, the first solder joint 142 may be divided by the first discontinuous zone 140 into two parts that are arranged opposite at intervals. The first discontinuous zone 140 may preferably be disposed at the center of the first solder joint 142, and the first confluence grid line 112 passing through the center of first solder joint 142 connects the first edge busbar 131 and the first busbar 13 adjacent to the first edge busbar 131, so as to converge the first edge busbars 131.

In such cases, in order to avoid the formation of a first discontinuous zone 140 in the first solder joint 142 from affecting the subsequent welding, the first solder joint 142 may be set to be longer or wider to ensure the reliability of subsequent welding.

### Embodiment 7

In further, referring to FIG. 6, in some embodiments, the first discontinuous zone 140 may be located between two adjacent first solder joints 142. The distance between the first confluence grid line 112 passing through the first discontinuous zone 140 and the centerline between two adjacent first solder joints 142 is less than or equal to 20 mm, that is, the distance between the first confluence grid line 112 and the midpoint between two adjacent first solder joints 142 is less than or equal to 20 mm.

A suitable distance may be maintained between the first confluence grid line 112 and the first solder joint 142 to avoid the problem of false soldering during welding the first solder joint 142 due to the presence of the first confluence grid line 112, and the distance between the first confluence grid line 112 and the center between two first solder joints 142 may also be maintained within a reasonable range, so that the convergence effect will not be affected due to the significantly different convergence path of the current from the first collection grid lines 111 on the upper and lower sides of the first confluence grid line 112.

It may be understood that, in some embodiments, during printing process, the height of the first confluence grid line 112 is the same as or even slightly higher than that of the first solder joint 142. The distance between the first confluence grid line 112 and the first solder joint 142 may not be too small, otherwise the certain height difference between them may lead to false soldering during welding. Therefore, a distance less than or equal to 20 mm between the first confluence grid line 112 and the centerline of two adjacent first solder joints 142 may effectively avoid the false soldering and increased defect rate due to the small distance between them.

If, meanwhile, a large distance deviation between the first confluence grid line 112 and the centerline between two first solder joints 142 will lead to a significant difference in the convergence path and corresponding losses when convergence is made from the upper and lower sides of the first confluence grid line 112, which affects the convergence effect. Therefore, a distance of less than or equal to 20 mm between the first confluence grid line 112 and the centerline between two adjacent first solder joints 142 may effectively ensure the convergence effect of the first confluence grid lines 112.

In further, in such an embodiment, the distance between the first confluence grid line 112 passing through the first discontinuous zone 140 and the centerline between the two adjacent first solder joints 142 may be less than or equal to 10 mm. A distance within this preferred range between the first confluence grid line 112 and the two first solder joints 142 may effectively ensure the convergence effect.

In such an embodiment, the first discontinuous zone 140 is located between two adjacent first solder joints 142. The distance between the first confluence grid line 112 passing through the first discontinuous zone 140 and the centerline between two adjacent first solder joints 142 may be preferably less than or equal to 5 mm, preferably less than or equal to 3 mm, and most preferably 1 mm, so that the first confluence grid line 112 may overlap with the centerline between the two first solder joints 142 as much as possible to ensure a basically same convergence path from the top to bottom direction and a better convergence effect.

Specifically, in such an embodiment, ideally, the first confluence grid line 112 is disposed at the centerline of two adjacent first solder joints 142, that is, the first confluence grid line 112 coincides the centerline between two adjacent first solder joints 142, with a distance of 0, providing exactly the same paths in all directions and the best convergence effect. In some embodiments, of course, the distance between the first confluence grid line 112 passing through the first discontinuous zone 140 and the centerline between two adjacent first solder joints 142 may also be 1 mm, 0.8 mm, 0.6 mm, 0.4 mm, 0.2 mm, and 0.1 mm, most preferably 0, which are subject to no limitations here.

### Embodiment 8

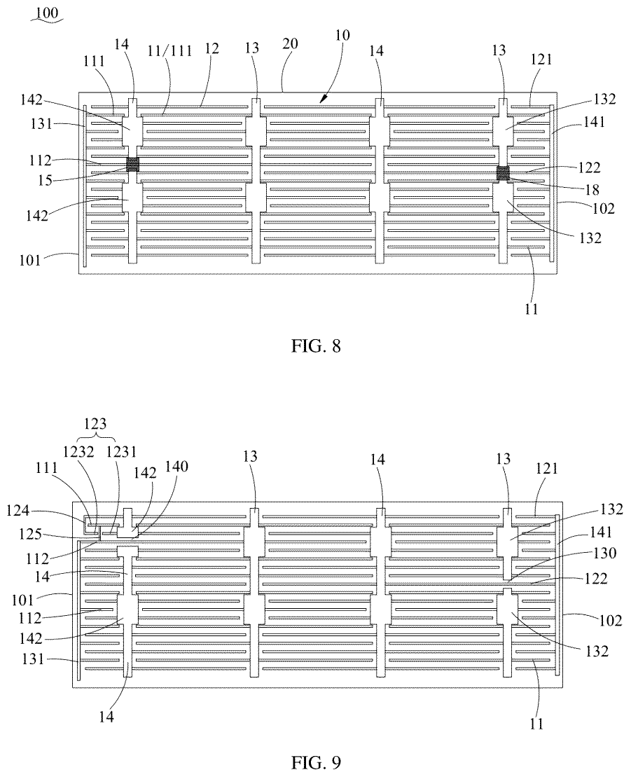

Referring to FIG. 8, in some embodiments, the first discontinuous zone 140 may be covered with a first insulation layer 15.

Covering the first discontinuous zone 140 with a first insulation layer 15 may avoid electric leakage caused by the contact between the welding rod and the first confluence grid line 112 when welding the first solder joint 142.

Specifically, for the purpose of insulation, the size of the first insulation layer 15 may be equal to or slightly larger than that of the first discontinuous zone 140, that is, only the area on the second busbar 14 corresponding to the first discontinuous zone 140 is covered with the first insulation layer 15, and no first insulation layer 15 is disposed in other areas. The first insulation layer 15 may be an insulating adhesive.

### Embodiment 9

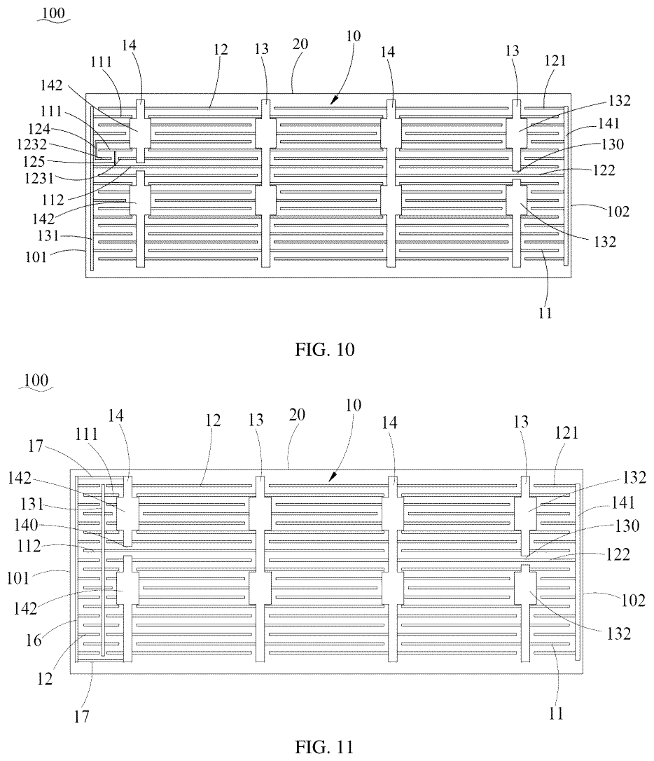

Referring to FIGS. 9 and 10, in some embodiments, the second finger 12 may include a first discontinuous grid line 123 adjacent to the first confluence grid line 112 and a first curved grid line 124 adjacent to the first discontinuous grid line 123. The first discontinuous grid line 123 includes a first connection section 1231 and a second connection section 1232 which are disposed at intervals, and a first gap is formed between the first connection section 1231 and the second connection section 1232.

The first connection section 1231 is connected to the second busbar 14 adjacent to the first edge busbar 131, and the second connection section 1232 connecting to the first curved grid line 124 to encircle the end of the first collection grid line 111 between the first discontinuous grid line 123 and the first curved grid line 124, and the first collection grid line 111 located between the first discontinuous grid line 123 and the first curved grid line 124 is not connected to the first edge busbar 131 but to the first confluence grid line 112 through the first penetrating grid line 125 that passes the first gap.

In this way, the connection between the first curved grid line 124 and the first connection section 1231 may surround the first collection grid line 111 between the first discontinuous grid line 123 and the first curved grid line 124, while the connection between the first confluence grid line 112 and the surrounded first collection grid line 111 through the first penetrating grid line that passes the first gap may converge the first collection grid lines 111 that are not connected to the first edge busbar 131.

Specifically, in the embodiment shown in FIG. 9, the first discontinuous grid line 123 is adjacent to the first confluence grid line 112, the first curved grid line 124 may be disposed in the upper left corner of the back-contact solar cell 100. The first confluence grid line 112 may penetrate the first solder joint 142, that is, the first discontinuous zone 140 is located on the first solder joint 142, and the end of the first curved grid line 124 bends towards the first confluence grid line 112 to connect the second connection section 1232 of the first discontinuous grid line 123, and both the first curved grid line 124 and the second connection section 1232 encircle the first collection grid line 111 adjacent to the first curved grid line 124. The first collection grid line 111 encircled by the first curved grid line 124 is not connected to the first edge busbar 131, but to the first confluence grid line 112 for convergence through the first penetrating grid line 125 that passes through the first gap. In such an embodiment, it may be understood that the second polar region may match the corresponding first curved grid line 124 in shape.

In addition, in the embodiment shown in FIG. 10, the first curved grid line 124 may also be located in the middle of the back-contact solar cell 100, and the first discontinuous zone 140 is located between two adjacent first solder joints 142, which are subject to no limitations here. Of course, in other embodiments, the first curved grid line 124 may also be disposed in any other position of the back-contact solar cell 100, and single or a plurality of first curved grid lines 124 and first discontinuous grid lines 123 may be provided, which are subject to no limitations here.

### Embodiment 10

Referring to FIG. 11, in some embodiments, the electrode structure 10 may also include a first confluence electrode 16 adjacent to the first edge busbar 131, no solder joints are provided on the first confluence electrode 16. The first confluence electrode 16, which is closer to the first edge 101 than to the first edge busbar 131, is connected to the second finger 12 located between the first edge busbar 131 and the first confluence electrode 16, that is, the first confluence electrode 16 has the same polarity as the second finger 12 and the second busbar 14.

The electrode structure 10 also includes at least one first connection grid line 17 located at the end of the first busbar 13 and the end of the second busbar 14. The first connection grid line 17 is not disconnected at the first edge busbar 131, and the first connection grid line 17 is connected to the first confluence electrode 16 and the second busbar 14 adjacent to the first edge busbar 131.

In this way, the use of the first confluence electrode 16, which is closer to the first edge 101 than to the first edge busbar 131, may converge the current collected by the second finger 12 located in the area near the first edge 101 to the second busbar 14 adjacent to the first edge busbar 131 through the first connection grid line 17, without welding on the first confluence electrode 16, which may avoid cracking due to stress concentration during welding at the edges, and it is not required to set the fingers in the edge area with the same polarity as in FIG. 3 of the prior art, which may lead to poor photoelectric conversion performance.

Specifically, as shown in FIG. 11, the first confluence electrode 16 has the same polarity as the second busbar 14, and a second finger 12 (i.e. the one located near the first edge 101) that is disconnected at the first edge busbar 131 is provided between the first confluence electrode 16 and the first edge busbar 131. The first confluence electrode 16 may converge the current collected by the second finger 12 located in the edge area to the adjacent second busbar 14 through the first connection grid line 17.

In further, as shown in FIG. 11, in some embodiments, the number of the first connection grid line 17 is two, two first connection grid lines 17 are located at both ends of the first busbar 13 and the second busbar 14, respectively.

The two first connection grid lines 17 ensure the uniform convergence of the second fingers 12 in the edge area near the first edge 101, avoiding reduced efficiency due to a long convergence path.

Specifically, as shown in FIG. 11, two first connection grid lines 17 may be connected to both ends of the first confluence electrode 16 and ends of the adjacent second busbars 14, that is, the first connection grid line 17, the first confluence electrode 16, and the adjacent second busbars 14 jointly enclose the first edge busbar 131 and the finger between the first edge busbar 131 and the first confluence electrode 16.

As shown in FIG. 11, in some embodiments, the spacing between the first edge busbar 131 and the second busbar 14 adjacent to the first edge busbar 131 may be smaller than that between the other adjacent first busbars 13 and the second busbars 14, that is, in such a case, the first busbars 13 and the second busbars 14 may be arranged at uneven intervals, and the distance between the first edge busbar 131 and the adjacent second busbar 14 may be smaller, with or without fingers between them, which are subject to no restrictions here.

In some embodiments, the first confluence electrode 16 is located at the first edge 101. Specifically, “the first confluence electrode 16 is located at the first edge 101” may be understood that the first confluence electrode is disposed on the edge line of the back-contact solar cell 100 or without additional fingers are disposed between the first confluence electrode 16 and the edge line of the back-contact solar cell 100.

### Embodiment 11

In some embodiments, the width of the first connection grid line 17 may be 80 um-1.5 mm.

In this way, the first connection grid lines 17 having a rational width within the range of 80 um-1.5 mm may ensure its convergence effect, and prevent the first connection grid lines 17 from overheating or even melting since the first connection grid lines 17 with too small width fail to withstand the current from the first confluence electrode 16, and also avoid the waste of paste as a result of the first connection grid lines 17 with too large width.

Specifically, in such embodiments, the width of the first connection grid line 17 may be any one of the values from 80 um, 100 um, 200 um, 300 um, 400 um, 500 um, 600 um, 700 um, 800 um, 900 um, 1 mm, 1.1 mm, 1.2 mm, 1.3 mm, 1.4 mm, 1.5 mm, or 80 um-1.5 mm, which are subject to no restrictions here.

In further, in some embodiments, the width of the first connection grid line 17 may be preferably greater than 1.5 times that of the second finger 12.

The first connection grid line 17 with a width greater than 1.5 times that of the second finger 12 may ensure a better confluence effect and reliability.

Specifically, it may be understood that in the embodiment of the present application, the current that flows through the first connection grid line 17 is the converged one flowing through the first confluence grid line 112. The width of the first connection grid line 17 therefore may be preferably 1.5 times larger than that of the second grid line 11, ensuring the first connection grid line 17 with a larger width and better convergence reliability.

### Embodiment 12

Referring to FIG. 6 again, in some embodiments, the second busbar 14 may include a second edge busbar 141 (i.e. the rightmost second busbar 14 in FIG. 6) located on one side near a second edge 102 (i.e. the right edge in FIG. 6) of the back-contact solar cell 100, the second edge 102 and the first edge 101 arranged opposite to each other;

The plurality of second fingers 12 may include at least one second collection grid line 121 and at least one second confluence grid line 122. The second collection grid line 121 is disconnected at the first busbar 13, and at least one second discontinuous zone 130 is formed at the first busbar 13 adjacent to the second edge busbar 141 (i.e. the first first busbar 13 from right to left in FIG. 6). One end of the second confluence grid line 122 is connected to the second edge busbar 141, and the other end of the at least one second confluence grid line passes through a second discontinuous zone 130 and is connected to the second busbar 14 adjacent to the second edge busbar 141 (i.e. the first second busbar 14 from right to left in FIG. 6).

The second collection grid line 121 in the second finger 12 is disconnected at the first busbar 13, and the second edge busbar 141 in the second busbar 14 is connected to the second collection grid line 121 in the second finger 12 to collect the current in the second polar region near the second edge 102, and the second confluence grid line 122 passes through the second discontinuous zone 130 on the first busbar 13 adjacent to the second edge busbar 141 to connect the second edge busbar 141 as well as the second busbar 14 adjacent to the second edge busbar 141. The current collected by the second edge busbar 141 may be transmitted for convergence and collection purpose through the second confluence grid line 122 to the second busbar 14 adjacent to the second edge busbar 141. In this way, the second edge busbar 141 is located on the side near the second edge 102 of the back-contact solar cell 100. The second edge busbar 141 may directly connect and converge with the first busbar 13 adjacent to the second confluence grid line 122 through the second confluence grid line 122. Compared to the electrode pattern design in FIG. 2 of the prior art, the convergence of adjacent edge area of the second edge 102 without welding on the second edge busbar 141 may avoid stress concentration during welding and improve the yield and reliability of assembly. Moreover, compared to the third type of electrode pattern design of the prior art, the photogenerated electron holes near the first edge may, without spanning a long distance, reach the opposite region to collect the current and fully ensures a high photoelectric conversion.

In the embodiment shown, “second edge 102” refers to the right edge in FIG. 6, and “the second edge busbar 141 is located on the side near the second edge 102” means that the second edge busbar 141 is the rightmost second busbar 14 in FIG. 6, that is, the second edge busbar may be a certain distance from the second edge 102 of the back-contact solar cell 100, or the second edge busbar may also be directly disposed on the second edge 102 of the back-contact solar cell 100 (i.e. the right edge in FIG. 6), which are subject to no restrictions here.

In the embodiment of the present application, “at least one second discontinuous zone 130 is formed at the first busbar 13 adjacent to the second edge busbar 141” means that the first busbar 13 adjacent to the second edge busbar 141, a discontinuous structure, is separated at the second discontinuous zone 130, that is, the second edge busbar 141 is separated into at least two parts by the second discontinuous zone 130.

It may also be understood that in the process of forming the first busbar 13 adjacent to the second edge busbar 141, a screen plate may be used to cover the position corresponding to the second discontinuous zone 130, and the first busbar 13 adjacent to the second edge busbar 141 with a second discontinuous zone 130 may be formed through printing or electroplating and evaporation.

In further, as shown in FIG. 6, it may be understood that in the embodiment of the present application, the first finger 11 and the second finger 12 are alternatively disposed between the second edge busbar 141 and the first busbar 13 adjacent to the second edge busbar 141. The second collection grid line 121 in the second finger 12 is connected to the second edge busbar 141, and the first finger 11 is connected to the first busbar 13 adjacent to the second edge busbar 141, and the second confluence grid line 122 passing through the second discontinuous zone 130 on the first busbar 13 adjacent to the second edge busbar 141 is connected to the first busbar 13 adjacent to the second edge busbar 141.

The second edge busbar 141 may converge the current collected by the second collection grid line 121 between the second edge busbar 141 and the first busbar 13 adjacent to the second edge busbar 141, and the current then flows through the second collection grid line 122 to the second busbar 14 adjacent to the second edge busbar 141, so that the current generated in the second polar region of the edge region near the second edge 10 is collected and converged, without welding on the second edge busbar 141, which avoids the occurrence of cracks on the edge of the back-contact solar cell 100 during the welding.

Similarly, like the first confluence line 112, in some embodiments, since the second confluence grid line 122 is connected to the second edge busbar 141 and the second busbar 14 adjacent to the second edge busbar 141 to converge the second edge busbar 141 and the adjacent first busbar 13, the second confluence grid lines 122 may preferably be copper grid lines with smaller current loss.

In some embodiments, the second edge busbar 141 is located at the second edge 102 of the back-contact solar cell 100. Specifically, “the second edge busbar 141 is located at the second edge 102 of the back-contact solar cell 100” may be understood as being disposed on the edge line of the back-contact solar cell 100 or without additional fingers between the second edge busbar 141 and the edge line of the back-contact solar cell 100.

### Embodiment 13

In further, like the first edge busbar 131, in some embodiments, no solder joints are provided on the second edge busbar 141 for welding, which may save solder joint related materials and reduce costs while also avoiding edge cracks during the welding process.

In some embodiments, the second edge busbar 141 is not used for welding so that cracks caused by welding at the edges are avoided.

In such a case, it may be understood that the second edge busbar 141 is not provided with solder joints and/or not used for welding, or solder joints are provided on the second edge busbar 141 but not used for welding, preferably no solder joints are provided on the second edge busbar 141 and used for welding.

### Embodiment 14

In some embodiments, like the first confluence grid lines 112, a plurality of second confluence grid lines 122 and a plurality of second discontinuous zones 130 may be provided, and each second discontinuous zone 130 corresponds to at least one second confluence grid line 122.

The second edge busbar 141 and the second busbar 14 adjacent to the second edge busbar 141 may be connected through a plurality of second confluence grid lines 122 to improve the confluence efficiency.

Specifically, in such embodiments, preferably a second discontinuous zone 130 corresponds to a second confluence grid line 122, in order to avoid poor welding (such as false soldering) with the second busbar 14 of the second edge busbar 141 due to the excessive width of the second discontinuous zone 130, and to ensure the reliability of welding.

It should be noted that FIG. 6 only presents a second confluence grid line 122, and some of the fingers and busbars of the electrode structure, which merely serve as examples. It may be understood that in some embodiments, a plurality of first fingers 11 and second fingers 12, as well as second confluence grid lines 122 may also be provided below the second confluence grid line 122 in FIG. 6. The specific number may be determined based on the size of the back-contact solar cell 100, which are subject to no restrictions here.

### Embodiment 15

In some embodiments, a plurality of second confluence grid lines 122 are symmetrically arranged along the centerline of the back-contact solar cell 100 in the arrangement direction of the first finger 11 and the second finger 12.

A plurality of second confluence grid lines 122 which are symmetrically disposed may ensure that each second confluence grid line 122 has basically the same convergence path when collecting current on the second edge busbar 141, avoiding the current convergence with a larger overall losses due to the significant differences in the convergence paths that may result in varied losses on different paths.

Specifically, in such an embodiment, a plurality of second confluence grid lines 122 are symmetrically disposed along the centerline of back-contact solar cell 100 in the arrangement direction of the first finger 11 and the second finger 12, that is, the second confluence grid lines 122 are symmetrically disposed in the two vertically symmetric areas of the back-contact solar cell 100, and the distance between any two adjacent connection points between the second edge busbar 141 and each second confluence grid lines 122 is the same. During confluence, the confluence from the second edge busbar 141 to each second confluence grid line 122 basically has the same confluence path and loss, ensuring the confluence performance and improving the confluence efficiency.

It may be understood that, of course, in some embodiments, a single second confluence grid line 122 may also be disposed at the center of the back-contact solar cell 100, that is, the connection point between the single second confluence grid line 122 and the second edge busbar 141 is located at the midpoint of the second edge busbar 141.

In this way, the use of the single second confluence grid line 122 at the center position ensures that the current collected by the second confluence grid line 121 has basically the same convergence path, avoiding significant differences in convergence paths that may lead to increased overall losses and ensuring the convergence effect.

Specifically, in such an embodiment, a single second confluence grid line 122 may be connected at the midpoint of the second edge busbar 141 to divide the back-contact solar cell 100 into two vertically symmetrical regions, so that the current collected by the second collection grid line 121 in the upper and lower regions has basically the same confluence path on the second edge busbar 141, ensuring the confluence effect.

### Embodiment 16

In some embodiments, the width of the second confluence grid line 122 may be 80 um-1.5 mm.

In this way, the second confluence grid lines 122 having a rational width within the range of 80 um-1.5 mm may ensure its convergence effect, and prevent the second confluence grid lines 122 from overheating or even melting since the second confluence grid lines 122 with too small width fail to withstand the current from the second edge busbar 141, and also avoid the waste of paste as a result the second confluence grid lines 122 with too large width.

Specifically, in such embodiments, the width of the second confluence grid line 122 may be any one of the values from 80 um, 100 um, 200 um, 300 um, 400 um, 500 um, 600 um, 700 um, 800 um, 900 um, 1 mm, 1.1 mm, 1.2 mm, 1.3 mm, 1.4 mm, 1.5 mm, or 80 um-1.5 mm, which are subject to no restrictions here.

In further, in some embodiments, the width of the second confluence grid line 122 may be preferably greater than 1.5 times that of the second collection grid line 121.

The second confluence grid line 122 with a width greater than 1.5 times that of the second collection grid line 121 may ensure a better confluence effect and reliability.

Specifically, it may be understood that in the embodiment of the present application, the current that flows through the second confluence grid line 122 is the converged one flowing through the second edge busbar line 141. The width of the second confluence grid line 122 therefore may be preferably 1.5 times larger than that of the first connection grid line 111, ensuring the second confluence grid line 122 with a larger width and better convergence reliability.

In some embodiments, the distance between the two first fingers 11 adjacent to the second confluence grid line 122 is greater than the distance between the other adjacent first fingers 11.

In this way, a larger spacing between the two first fingers 11 adjacent to the second confluence grid line 122 provides the second confluence grid line 122 with a larger width, ensuring the convergence effect and reliability.

### Embodiment 17

Referring to FIG. 6, in some embodiments, a plurality of second solder joints 132 are spaced on the first busbar 13 adjacent to the second edge busbar 141;

The second discontinuous zone 130 is located between two adjacent second solder joints 132.

The arrangement of the second discontinuous zone 130 at two adjacent second solder joints 132 may, while realizing the convergence, ensure the integrity of the second solder joint 132 and support the welding with the first busbar 13 adjacent to the second edge busbar 141.

Specifically, in such an embodiment, a plurality of second solder joints 132 may be evenly spaced on the first busbar 13 adjacent to the second edge busbar 141 (FIG. 6 only exemplify two first solder joints 142). Preferably a single second discontinuous zone 130 is provided between the adjacent second solder joints 132 and a single second confluence grid line 122 corresponding to the second discontinuous zone 130 is provided, so that at least one second confluence grid line 122 is provided between each two second solder joints 132 to reduce the number and the width of the second discontinuous zone 130 between adjacent second solder joints 132, and to avoid affecting the welding with the first busbar 13 adjacent to the second edge busbar 141.

In such an embodiment, the distance between two adjacent second solder joints 132 on the first busbar 13 adjacent to the second edge busbar 141 may be greater than 5 mm, preferably greater than 9 mm. In some embodiments, in order to reduce the use of paste at the second solder joint 132 of the same size, the distance between two adjacent second solder joints 132 may be greater than 11 mm but less than or equal to 45 mm.

In further, in such embodiments, the spacing between two adjacent second solder joints 132 may be preferably greater than 11 mm but less than or equal to 30 mm. The second solder joints 132 having a spacing within this optimal range may ensure the number of second solder joints 132 to provide welding reliability without poor welding, and also avoid increasing costs due to the excessive number of second solder joints 132.

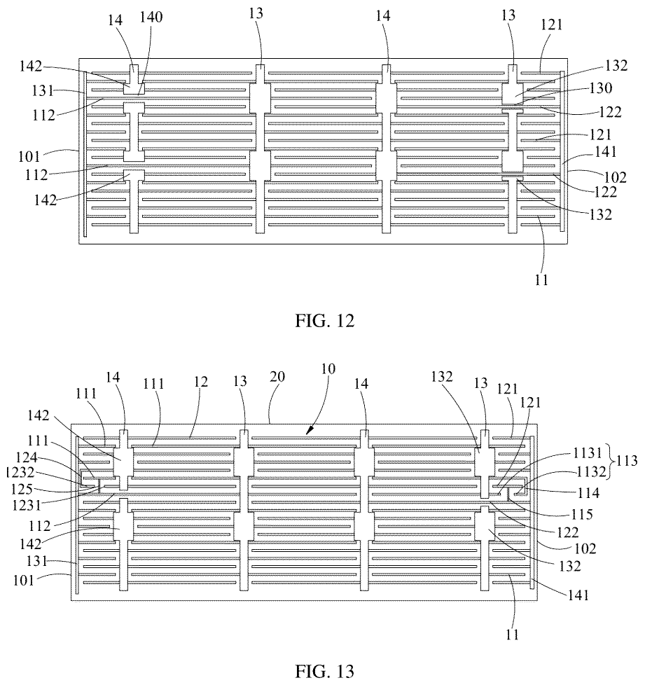

Of course, referring to FIG. 12, in some embodiments, the second discontinuous zone 130 may also be formed on the second solder joint 132, that is, a second discontinuous zone 130 is provided on the second solder joint 132.

A second discontinuous zone 130 is formed on each second solder joint 132, and both the second discontinuous zones 130 and the second confluence grid lines 122 are uniformly arranged to ensure the convergence effect.

Specifically, as shown in FIG. 12, in such a case, the second solder joint 132 may be divided by the second discontinuous zone 130 into two parts that are arranged opposite at intervals. The second discontinuous zone 130 may preferably be disposed at the center of the second solder joint 132, and the second confluence grid line 122 passing through the center of second solder joint 132 connects the second edge busbar 141 and the second busbar 14 adjacent to the second edge busbar 141, so as to converge the second edge busbars 141.

In such cases, in order to avoid the formation of a second discontinuous zone 130 on the second solder joint 132 from affecting the subsequent welding, the second solder joint 132 may be set to be longer or wider to ensure the reliability of subsequent welding.

### Embodiment 18

In further, referring to FIG. 6, in some embodiments, the second discontinuous zone 130 may be located between two adjacent second solder joints 132. The distance between the second confluence grid line 122 passing through the second discontinuous zone 130 and the centerline between two adjacent second solder joints 132 is less than or equal to 20 mm, that is, the distance between the second confluence grid line 122 and the midpoint between two adjacent second solder joints 132 is less than or equal to 20 mm.

A suitable distance may be maintained between the second confluence grid line 122 and the second solder joint 132 to avoid the problem of false soldering during welding due to the presence of the second confluence grid line 122, and the distance between the second confluence grid line 122 and the center between two second solder joints 132 may also be maintained within a reasonable range, so that the convergence effect will not be affected due to the significantly different convergence path of the current from the first collection grid lines 111 on both sides of the second confluence grid line 122.

It may be understood that, in some embodiments, during printing process, the height of the second confluence grid line 122 is the same as or even slightly higher than that of the second solder joint 132. The distance between the second confluence grid line 122 and the second solder joint 132 may not be too small, otherwise the certain height difference between them may lead to false soldering during welding. Therefore, a distance less than or equal to 20 mm between the second confluence grid line 122 and the centerline of two adjacent second solder joint 132 may effectively avoid the false soldering and increased defect rate due to the small distance between them.

If, meanwhile, a large distance deviation between the second confluence grid line 122 and the centerline between two second solder joints 132 will lead to a significant difference in the convergence path and corresponding losses when convergence is made from the upper and lower sides of the second confluence grid line 122, which affects the convergence effect. Therefore, a distance of less than or equal to 20 mm between the second confluence grid line 122 and the centerline between two adjacent second solder joints 132 may effectively ensure the convergence effect of the second confluence grid lines 122.

In further, in such an embodiment, the distance between the second confluence grid line 122 passing through the second discontinuous zone 130 and the centerline between the two adjacent second solder joints 132 may be less than or equal to 10 mm. A distance within this preferred range between the second confluence grid line 122 and the two second solder joints 132 may effectively ensure the convergence effect.

In such an embodiment, the second discontinuous zone 130 is located between two adjacent second solder joints 132. The distance between the second confluence grid line 122 passing through the second discontinuous zone 130 and the centerline between two adjacent second solder joints 132 may be preferably less than or equal to 5 mm, preferably less than or equal to 3 mm, and most preferably 1 mm, so that the second confluence grid line 122 may overlap with the centerline between the two second solder joints 132 as much as possible to ensure a basically same convergence path from the top to bottom direction and a better convergence effect.

Specifically, in such an embodiment, ideally, the second confluence grid line 122 is disposed at the centerline of two adjacent second solder joints 132, that is, the second confluence grid line 122 coincides the centerline between two adjacent second solder joints 132, with a distance of 0, providing exactly the same paths in all directions and the best convergence effect. In some embodiments, of course, the distance between the second confluence grid line 122 passing through the second discontinuous zone 130 and the centerline between two adjacent first solder joints 142 may also be 1 mm, 0.8 mm, 0.6 mm, 0.4 mm, 0.2 mm, and 0.1 mm, most preferably 0, which are subject to no limitations here.

### Embodiment 19

Referring to FIG. 8, in some embodiments, the second discontinuous zone 130 may be covered with a second insulation layer 18.

Covering the second discontinuous zone 130 with the second insulation layer 18 may avoid electric leakage caused by the contact between the welding rod and the second confluence grid line 122 when welding the second solder joint 132.

Specifically, for the purpose of insulation, the size of the second insulation layer 18 may be equal to or slightly larger than that of the second discontinuous zone 130, that is, only the area on the first busbar 13 corresponding to the second discontinuous zone 130 is covered with the second insulation layer 18, and no second insulation layer 18 is disposed in other areas. The second insulation layer 18 may be an insulating adhesive.

### Embodiment 20

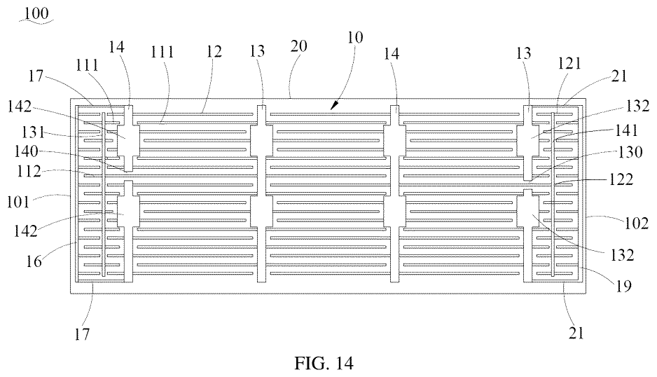

Referring to FIG. 13, in some embodiments, the second finger 12 may include a second discontinuous grid line 122 adjacent to the second confluence grid line 113 and a second curved grid line 114 adjacent to the second discontinuous grid line 113. The second discontinuous grid line 113 includes a third connection section 1131 and a fourth connection section 1132 which are disposed at intervals, and a second gap is formed between the third connection section 1131 and the fourth connection section 1132;

The third connection section 1131 is connected to the first busbar 13 adjacent to the second edge busbar 141, and the fourth connection section 1232 is connected to the second curved grid line 114 to encircle an end of the second collection grid line 121 between the second discontinuous grid line 113 and the second curved grid line 114, and the second collection grid line 121 between the second discontinuous grid line 113 and the second curved grid line 114 is not connected to the second edge busbar 141, but to the second confluence grid line 122 through the second penetrating grid line 115 that passes the second gap.

In this way, the connection between the second curved grid line 114 and the third connection section 1131 may encircle the second collection grid line 121 between the second discontinuous grid line 113 and the second curved grid line 114, while the connection between the second confluence grid line 122 and the surrounded second collection grid line 121 through the second penetrating grid line 115 that passes the second gap may converge the second collection grid lines 121 that are not connected to the second edge busbar 141.

Specifically, in the embodiment shown in FIG. 13, the second discontinuous grid line 113 is adjacent to the second confluence grid line 122, the second curved grid line 114 may be disposed in the middle of the back-contact solar cell 100. The end of the second curved grid line 114 bends towards the second confluence grid line 122 to connect to the fourth connection section 1132 of the second discontinuous grid line 113, and both the second curved grid line 114 and the fourth connection section 1132 encircle the second collection grid line 121 adjacent to the second curved grid line 114. The second collection grid line 121 wrapped by the second curved grid line 114 is not connected to the second edge busbar 141, but to the second confluence grid line 122 for convergence through the second penetrating grid line 115 that passes through the second gap. In such an embodiment, it may be understood that the first polar region may match the corresponding second curved grid line 114 in shape.

In addition, in some embodiments, the second curved grid line 114 may also be disposed in any other position of the back-contact solar cell 100, and single or a plurality of second curved grid lines 114 and second discontinuous grid lines 113 may be provided, which are subject to no limitations here.

### Embodiment 21

Referring to FIG. 14, in some embodiments, the electrode structure 10 may also include a second confluence electrode 19 adjacent to the second edge busbar 141, without solder joints on the second confluence electrode 19. The second confluence electrode 19 is closer to the second edge 102 than the second edge busbar 141, and the second confluence electrode 19 is connected to the first finger 11 located between the second edge busbar 141 and the second confluence electrode 19, that is, the second confluence electrode 19 has the same polarity as the first finger 11 and the first busbar 13.

The electrode structure 10 also includes at least one second connection grid line 21 located at the end of the first busbar 13 and the end of the second busbar 14. The second connection grid line 21 is not disconnected at the second edge busbar 141, and is connected to the second confluence electrode 19 and the first busbar 13 adjacent to the second edge busbar 141.

The use of the second confluence electrode 19 closer to the second edge 102 than the second edge busbar 141 may, through the second connection grid line 19, without welding on the first confluence electrode 16, converge the current collected by the first finger 11 in the area near the second edge 102 to the first busbar 11 adjacent to the second edge busbar 141, which may avoid cracking due to stress concentration during welding at the edges, and it is not required to set the fingers in the edge area with the same polarity as in FIG. 3 of the background art, which may lead to poor photoelectric conversion performance.

Specifically, as shown in FIG. 14, the second confluence electrode 19 has the same polarity as the first busbar 14, and a first finger 11 (i.e. the one located near the second edge 101) that is disconnected at the second edge busbar 141 is provided between the second confluence electrode 19 and the second edge busbar 141. The second confluence electrode 19 may, through the second connection grid line 21, converge the current collected by the first finger 11 in the edge area to the adjacent first busbar 13.

In further, as shown in FIG. 14, in some embodiments, the number of the second connection grid lines 21 is two, two second connection grid lines 21 are located at both ends of the first busbar 13 and of the second busbar 14, respectively.

The two second connection grid lines 21 ensure the uniform convergence of the first fingers 11 in the edge area, avoiding reduced efficiency due to a long convergence path.

Specifically, as shown in FIG. 14, two second connection grid lines 21 may be connected to both ends of the second confluence electrode 19 and of the adjacent first busbar 13, that is, the second connection grid line 21, the second confluence electrode 19, and the adjacent first busbar 13 jointly enclose the second edge busbar 141 and the finger between the second edge busbar 141 and the second confluence electrode 19.

As shown in FIG. 14, in some embodiments, the spacing between the second edge busbar 141 and the first busbar 13 adjacent to the second edge busbar 141 may be smaller than that between the other adjacent first busbars 13 and the first busbar 13, that is to say, in such a case, the first busbars 13 and the second busbar 14 may be arranged at uneven intervals, and the distance between the second edge busbar 141 and the adjacent first busbar 13 may be smaller, with or without fingers between them, which are subject to no restrictions here.

In some embodiments, the second confluence electrode 19 is located at the second edge 102. Specifically, “the second confluence electrode 19 is located at the second edge 1012” may be understood that the second confluence electrode is disposed on the edge line of the back-contact solar cell 100 or without additional fingers are disposed between the second confluence electrode 19 and the edge line of the back-contact solar cell 100.

### Embodiment 22

In some embodiments, the width of the second connection grid lines 21 may be 80 um-1.5 mm.

In this way, the second connection grid lines 21 having a rational width within the range of 80 um-1.5 mm may ensure its convergence effect, and prevent the second connection grid lines 21 from overheating or even melting since the second connection grid lines 21 with too small width fail to withstand the current from the second confluence electrode 19, and also avoid the waste of paste as a result of the second connection grid lines 21 with too large width.

Specifically, in such embodiments, the width of the second connection grid line 21 may be any one of the values from 80 um, 100 um, 200 um, 300 um, 400 um, 500 um, 600 um, 700 um, 800 um, 900 um, 1 mm, 1.1 mm, 1.2 mm, 1.3 mm, 1.4 mm, 1.5 mm, or 80 um-1.5 mm, which are subject to no restrictions here.

In further, in some embodiments, the width of the second connection grid line 21 may be preferably greater than 1.5 times that of the first finger 11.

The second connection grid line 21 with a width greater than 1.5 times that of the first finger 11 (for example, the first collection grid line 111) may ensure a better confluence effect and reliability.

Specifically, it may be understood that in the embodiment of the present application, the current that flows through the second connection grid line 21 is the converged one flowing through the second confluence grid line 122. The width of the second connection grid line 21 therefore may be preferably 1.5 times larger than that of the first finger line 11, ensuring the second connection grid line 21 with a larger width and better convergence reliability.

The following Table 1 presents performance test comparison between the back-contact solar cell using the electrode pattern in FIGS. 2 and 3 and the one using the electrode structure of the present application.

TABLE 1

| | | | | | Efficiency loss value (%) | |
|---|---|---|---|---|---|---|
| | | | | Conversion | when assuming that the | |
| | Voc | Jsc | FF | efficiency | edge area accounts for | |
| | (mV) | (mA/cm²) | (%) | (%) | 10% of the total area | Remarks |
| Contrasting | 744.1 | 42.28 | 83.24 | 26.18 | | Edge welding with |
| example 1 | | | | | | reliability issues |
| Contrasting | 743.8 | 30.56 | 80.48 | 18.30 | 0.788 | |
| example 2 | | | | | | |
| Present | 744.2 | 42.18 | 82.88 | 25.95 | 0.023 | |
| application | | | | | | |

The contrasting example 1 and 2 in Table 1 represent the technical solution using the electrode pattern in FIG. 2 and FIG. 3, respectively. As is well known, cell's conversion efficiency is a key performance evaluation indicator for back-contact solar cells. A higher value indicates better performance, and every 0.1% increase means a breakthrough for the industry. Table 1 reveals that the technical solution in FIG. 2, although having a high efficiency, faces welding reliability at the edge which leads to a decrease in yield. The solution in FIG. 3 which solves the yield and reliability of assembly, however, shows a significant reduce in the performance, with an overall conversion efficiency of only 18.3%. The efficiency loss in the edge area is up to 0.788%. The technical solution of the present application, while considering the yield and reliability of assembly, provides the overall conversion efficiency as high as 25.95%, which is much higher than the conversion efficiency in contrasting example 2. Moreover, the technical solution of the present application may reduce the efficiency loss in the edge area to 0.023%. The conversion efficiency tests of current back-contact solar cells show a repeatability of about +0.05%, and the efficiency loss is so low that it may not be monitored and may be ignored.

In conclusion, the technical solution of the present application may not only solve the problems of yield and reliability of the assembly, but also ensure the overall efficiency of the back-contact solar cells, while reducing the efficiency loss in the edge area.

In the description of the specification, the reference terms “some embodiments”, “illustrative embodiments”, “examples”, “specific examples”, or “some examples” refer to the specific features, structures, materials, or characteristics described in conjunction with the embodiments or examples included in at least one embodiment or example of the present application. The schematic expressions of the above terms in the specification do not necessarily refer to the same embodiments or examples. Moreover, the specific features, structures, materials, or characteristics described may be combined in an appropriate manner in any one or more embodiments or examples.

In addition, the above are only preferred embodiments of the present application that are not intended to limit the application. Any modifications, equivalent substitutions, and improvements made within the spirit and principles of the present application shall be included in the scope of protection of the present application.

1. An electrode structure for back-contact solar cell, wherein the back-contact solar cell comprises a first polar region and a second polar region which are alternatively arranged, and the electrode structure comprises:
a plurality of first fingers and a plurality of second fingers, which are alternately spaced, wherein the plurality of first fingers are used to collect current in the first polar region, and the plurality of second fingers are used to collect current in the second polar region; and
a plurality of first busbars and a plurality of second busbars, which are alternately spaced, wherein an arrangement direction of the first busbar and the second busbar is different from that of the first finger and the second finger; the plurality of first busbars are connected to the plurality of first fingers, and the plurality of second busbars are connected to the plurality of second fingers;
the plurality of first fingers comprise at least one a first collection grid line and at least one first confluence grid line, wherein the at least one first collection grid line is disconnected at the second busbars, and the plurality of first busbars comprise a first edge busbar located on a side near a first edge of the back-contact solar cell, and at least one first discontinuous zone is formed at the second busbar adjacent to the first edge busbars; one end of the at least one first confluence grid line is connected to the first edge busbar, and the other end of the at least one first confluence grid line passing through the at least one first discontinuous zone is connected to the first busbar adjacent to the first edge busbar;
the first edge busbar satisfies at least one of the following:
no solder joints are provided on the first edge busbar;
the first edge busbar is not used for welding;
the first edge busbar is located at the first edge.

2. The electrode structure according to claim 1, wherein a plurality of first confluence grid lines and first discontinuous zones are provided, and each first discontinuous zone corresponds to the at least one first confluence grid line, or
a plurality of first confluence grid lines are symmetrically arranged along a centerline of the back-contact solar cell in the arrangement direction of the first finger and the second finger; or
a single first confluence grid line is located at a center position of the back-contact solar cell.

3. (canceled)

4. The electrode structure according to claim 1, wherein a width of the first confluence grid line satisfies at least one of the following:
the width of the first confluence grid line is 80 um-1.5 mm;
the width of the first confluence grid line is greater than 1.5 times that of the first collection grid line.

5. The electrode structure according to claim 1, wherein a plurality of first solder joints are spaced at intervals on the second busbar adjacent to the first edge busbar;
the first discontinuous zone is located between two adjacent first solder joints or forms on the first solder joint.

6. The electrode structure according to claim 5, wherein the first discontinuous zone is located between two adjacent first solder joints, a single first discontinuous zone is located between two adjacent first solder joints.

7. The electrode structure according to claim 5, wherein the first discontinuous zone is located between two adjacent first solder joints, and a distance between the first confluence grid line passing through the first discontinuous zone and a centerline between two adjacent first solder joints is less than or equal to 20 mm, or
the distance between the first confluence grid line passing through the first discontinuous zone and the centerline between two adjacent first solder joints is less than or equal to 10 mm, or
the distance between the first confluence grid line passing through the first discontinuous zone and the centerline between two adjacent first solder joints is less than or equal to 5 mm, or
the distance between the first confluence grid line passing through the first discontinuous zone and the centerline between two adjacent first solder joints is less than or equal to 3 mm.

8-10. (canceled)

11. The electrode structure according to claim 1, wherein the electrode structure satisfies at least one of the following: the first discontinuous zone is covered with a first insulation layer;
a distance between two second fingers adjacent to the first confluence grid line is greater than a distance between the other adjacent second fingers, or
the second finger comprises a first discontinuous grid line adjacent to the first confluence grid line and a first curved grid line adjacent to the first discontinuous grid line; the first discontinuous grid line comprises a first connection section and a second connection section that are disposed at intervals, and a first gap is formed between the first connection section and the second connection section;
the first connection section is connected to the second busbar adjacent to the first edge busbar, and the second connection section is connected to the first curved grid line to encircle an end of the first collection grid line between the first discontinuous grid line and the first curved grid line; the first collection grid line located between the first discontinuous grid line and the first curved grid line is not connected to the first edge busbar, but to the first confluence grid line through a first penetrating grid line that passes through the first gap.

12. (canceled)

13. The electrode structure according to claim 1, wherein the electrode structure further comprises a first confluence electrode adjacent to the first edge busbar, and no solder joints are provided on the first confluence electrode; the first confluence electrode, which is closer to the first edge than to the first edge busbar, is connected to the second finger located between the first edge busbar and the first confluence electrode;
the electrode structure further comprises at least one first connection grid line located at ends of the first busbar and the second busbar; the at least one first connection grid line, which is not disconnected at the first edge busbar, is connected to the first confluence electrode and the second busbar adjacent to the first edge busbar.

14. The electrode structure according to claim 13, wherein the electrode structure satisfies at least one of the following: two first connection grid lines are provided and are respectively disposed at both ends of the first busbar and the second busbar;
a distance between the first edge busbar and the second busbar adjacent to the first edge busbar is smaller than that between the other adjacent first busbars and the second busbars, or
the first confluence electrode is located at the first edge, or
a width of the first connection grid line satisfies at least one of the following: the width of the first connection grid line is 80 um-1.5 mm; the width of the first connection grid line is greater than 1.5 times that of the second finger.

15-16. (canceled)

17. The electrode structure according to claim 1, wherein the second busbar comprises a second edge busbar disposed on one side near a second edge of the back-contact solar cell, and the second edge is opposite to the first edge;
the plurality of second fingers comprise at least one second collection grid line and at least one second confluence grid line; the at least one second collection grid line, is disconnected at the first busbar, at least one second discontinuous zone is formed at the first busbar adjacent to the second edge busbar; one end of the at least one second confluence grid line is connected to the second edge busbar, and the other end of the at least one second confluence grid line passing through the at least one second discontinuous zone is connected to the second busbar adjacent to the second edge busbar.

18. The electrode structure according to claim 17, wherein the second edge busbar satisfies at least one of the following: no solder joints are provided on the second edge busbar and/or the second edge busbar is not used for welding;
the second edge busbar is located at the second edge of the back-contact solar cell, or
a plurality of second confluence grid lines second discontinuous zones are provided, and each second discontinuous zone corresponds to the at least one second confluence grid line, or
a plurality of second confluence grid lines are symmetrically disposed along a centerline of the back-contact solar cell in the arrangement direction of the first finger and the second finger; or
a single second confluence grid line is located at a center position of the back-contact solar cell, or
a width of the second confluence grid line satisfies at least one of the following:
the width of the second confluence grid line is 80 um-1.5 mm;
the width of the second collection grid line is greater than 1.5 times that of the second collection grid line.

19-21. (canceled)

22. The electrode structure according to claim 17, wherein a plurality of second solder joints are spaced at intervals on the first busbar adjacent to the second edge busbar;
the second discontinuous zone is located between two adjacent second solder joints or forms on the second solder joint.

23. The electrode structure according to claim 22, wherein the second discontinuous zone is located between two adjacent second solder joints, and a single second discontinuous zone is located between the two adjacent second solder joints.

24. The electrode structure according to claim 22, wherein the second discontinuous zone is located between two adjacent second solder joints, and a distance between the second confluence grid line passing through the second discontinuous zone and a centerline between two adjacent second solder joints is less than or equal to 20 mm, or
the distance between the second confluence grid line passing through the second discontinuous zone and the centerline between two adjacent second solder joints is less than or equal to 10 mm, or
the distance between the second confluence grid line passing through the second discontinuous zone and the centerline between two adjacent second solder joints is less than or equal to 5 mm.

25-26. (canceled)

27. The electrode structure according to claim 17, wherein the electrode structure satisfies at least one of the following: the second discontinuous zone is covered with a second insulation layer;
a distance between two first fingers adjacent to the second confluence grid line is greater than a distance between the other adjacent first fingers, or
the first finger comprises a second discontinuous grid line adjacent to the second confluence grid line and a second curved grid line adjacent to the second discontinuous grid line; the second discontinuous grid line comprises a third connection section and a fourth connection section that are spaced at intervals, and a second gap is formed between the third connection section and the fourth connection section;
the third connection section is connected to the first busbar adjacent to the second edge busbar, and the fourth connection section is connected to the second curved grid line to encircle an end of the second collection grid line between the second discontinuous grid line and the second curved grid line; the second collection grid line located between the second discontinuous grid line and the second curved grid line is not connected to the second edge busbar, but to the second confluence grid line through a second penetrating grid line that passes the second gap.

28. (canceled)

29. The electrode structure according to claim 17, wherein the electrode structure further comprises a second confluence electrode adjacent to the second edge busbar, and no solder joints are provided on the second confluence electrode; the second confluence electrode, which is closer to the second edge than to the second edge busbar, is connected to the first finger located between the second edge busbar and the second confluence electrode;
the electrode structure further comprises at least one second connection grid line located at ends of the first busbar and the second busbar; the at least one second connection grid line, which is not disconnected at the second edge busbar, is connected to the second confluence electrode and the first busbar adjacent to the second edge busbar.

30. The electrode structure according to claim 29, wherein the electrode structure satisfies at least one of the following: two second connection grid lines are provided, and are respectively disposed at both ends of the first busbar and the second busbar;
a distance between the second edge busbar and the first busbar adjacent to the second edge busbar is smaller than that between the other adjacent second busbars and the first busbars, or
the second confluence electrode is disposed at the second edge, or
a width of the second connection grid line satisfies at least one of the following: the width of the second connection grid line is 80 um-1.5 mm; the width of the second connection grid line is greater than 1.5 times that of the first finger.

31-32. (canceled)

33. A back-contact solar cell, comprising an electrode structure, wherein the electrode structure is disposed on a back surface of the back-contact solar cell, the back-contact solar cell further comprises a first polar region and a second polar region which are alternatively arranged, and the electrode structure comprises:
a plurality of first fingers and a plurality of second fingers, which are alternately spaced, wherein the plurality of first fingers are used to collect current in the first polar region, and the plurality of second fingers are used to collect current in the second polar region; and
a plurality of first busbars and a plurality of second busbars, which are alternately spaced, wherein an arrangement direction of the first busbar and the second busbar is different from that of the first finger and the second finger; the plurality of first busbars are connected to the plurality of first fingers, and the plurality of second busbars are connected to the plurality of second fingers;
the plurality of first fingers comprise at least one first collection grid line and at least one first confluence grid line, wherein the at least one first collection grid line is disconnected at the second busbars, and the plurality of first busbars comprise a first edge busbar located on a side near a first edge of the back-contact solar cell, and at least one first discontinuous zone is formed at the second busbar adjacent to the first edge busbar; one end of the at least one first confluence grid line is connected to the first edge busbar, and the other end of the at least one first confluence grid line passing through the at least one first discontinuous zone is connected to the first busbar adjacent to the first edge busbar;
the first edge busbar satisfies at least one of the following: no solder joints are provided on the first edge primary, the first edge busbar is not used for welding;
the first edge busbar is located at the first edge.

34. A cell assembly, comprising the back-contact solar cell as claimed in claim 33.

35. A photovoltaic system, comprising the cell assembly as claimed in claim 34.
